(19) United States
(12) Patent Application Publication
(10) Pub. No.: US 2010/0258181 A1
(43) Pub. Date: Oct. 14, 2010

(54) HIGH EFFICIENCY SOLAR CELL STRUCTURES

(76) Inventors: Michael Tischler, Phoenix, AZ (US); Vladimir Odnoblyudov, Eagle, ID (US); Kevin A. Tetz, Boise, ID (US)

Correspondence Address: FOLEY & LARDNER LLP, P.O. BOX 80278, SAN DIEGO, CA, 92138-0278, US

(21) Appl. No.: 12/723,601

(22) Filed: Mar. 12, 2010

Related U.S. Application Data
(60) Provisional application No. 61/161,713, filed on Mar. 19, 2009.

(51) Int. Cl. H01L 31/02; H01L 31/18

(52) U.S. Cl. 136/256; 438/93; 257/E31.004

(57) ABSTRACT

Solar cell structures and methods of fabricating solar cell structures having increased efficiency are provided.

### CROSS REFERENCE TO RELATED APPLICATIONS

This application claims priority to U.S. Ser. No. 61/161,713 filed Mar. 19, 2009, which is incorporated herein in its entirety.

### BACKGROUND OF THE INVENTION

This application relates generally to solar cells or photovoltaic cells. More specifically, this application relates to high efficiency multi-band or intermediate band solar cells.

Solar cells may comprise any of a variety of electronic structures including those illustrated in FIG. 1. The simplest structure, illustrated in FIG. 1A, makes use of a single junction. In a single junction structure, an active region (or absorbing region) comprising a single bandgap material is used to capture a portion of the solar spectrum with photons having an energy greater than the bandgap of the active region in the solar cell. Upon absorption of a photon, an electron-hole pair is created that produces a DC current under the action of an electric field. The conversion efficiency for a single junction cell may have a peak near the bandgap of the active region and may decrease rapidly for higher and lower energies. Using a single bandgap to convert a substantial portion of the solar spectrum is therefore relatively inefficient, with a theoretical maximum efficiency of 35%. Actual observed efficiencies for devices of this structure, however, are typically on the order of about 15% to about 20%.

Conversion of the available solar spectrum to electrical energy may be improved by using multijunctions. Multijunction structures may be created by engineering multiple bandgaps into a single cell. This is illustrated schematically in FIG. 1B, in which individual cells with different bandgaps are grown monolithically on top of one another. In these structures, the ordering of the regions is such that the materials are grown in order of increasing bandgap. With this approach, a larger portion of the incident energy is able to be absorbed, thereby increasing the total efficiency of the cell. The theoretical maximum efficiency for a two-junction structure illuminated by natural sunlight is 50%, while that for a three-junction structure is 56%. Observed maximum efficiencies for multijunction cells, for example those based on lattice-matched GaInP/GaAs/Ge triple junction cells, may be as high as about 42%, with typical efficiencies of about 30%.

While multijunction solar cells achieve higher efficiency than single junction solar cells, they are significantly more difficult and costly to produce. Multijunction solar cells have many more regions within the solar cell structure than a single junction solar cell and the specific compositions, thicknesses, and doping levels within each of region must be very accurately controlled to optimize efficiency. The result of the added complexity and diversity of materials in the device is that multijunction solar cells cost considerably more to manufacture. So, while more efficient than single junction solar cells, multijunction solar cells have only found use in relatively cost-insensitive applications, for example space platforms, or in applications where very small cell areas may be leveraged, for example in concentrator systems.

A third type of solar cell, the multi-band, multi-transition or intermediate band solar cell (IBSC), has been proposed that may theoretically achieve the high efficiencies of multijunction solar cells with the relatively simple structure and low cost of single junction solar cells. FIG. 1C shows a schematic of an example of an IBSC. The active (or absorbing) region of the IBSC comprises an intermediate energy level between the valence and conduction bands. This provides for three optical transitions at three different energies, thus making it functionally similar to a triple junction solar cell. However, from a structural point of view, it is a single homogeneous material, thus making manufacturing complexity and cost similar to that of a single junction solar cell. The theoretical maximum efficiency under full solar concentration using this approach is approximately 63%. The inclusion of still additional bands using this technique promises even higher efficiencies, with four-band approaches providing a theoretical maximum efficiency of 72% under full solar concentration.

A number of approaches have been suggested for introducing the intermediate band or energy level in an IBSC. These include introduction of an electronegative atom into a host semiconductor, for example K. M. Yu et al, Appl. Phys. Lett. 88 (2006) 092110 and the use of quantum dots, for example A. Luque et al., J. Appl. Phys. 99 (2006) 094503. While the concept of an IBSC is quite old (see for example M. Wolf, Proc. IRE July (1960) 1246), and significant efforts have been made to reduce this to practice, there has not yet been a demonstration of a satisfactorily functional IBSC.

Much of the previous work has focused on formation of an intermediate band in a variety of semiconductor materials. As discussed above, one approach is to introduce a small fraction of highly electronegative atoms into a host semiconductor material. This has been shown to dramatically alter the band-structure of the host material by splitting the conduction band into two sub-bands. Because of the interaction between the two sub-bands, one sub-band is pushed to energy higher than the band-gap of the host semiconductor, and the other to a lower energy, thereby creating an additional energy level in the band structure. See, for example, K. M. Yu et al, Appl. Phys. Lett. 88 (2006) 092110. Characterization of these materials has provided evidence for the formation of the desired intermediate bands, however, this has still not yet led to the demonstration of a working IBSC.

There is accordingly a general need in the art for relatively low cost and relatively high efficiency solar cells, and in particular, methods to make working IBSCs.

### SUMMARY OF THE INVENTION

In the following description and claims, the terms “comprise” and “include,” along with their derivatives, may be used and are intended as synonyms for each other and mean that addition of unnamed extra elements is not precluded. In addition, in the following description and claims, the terms “coupled” and “connected,” along with their derivatives, may be used.

As used herein, the term “connected” may be used to indicate that two or more elements are in direct physical or electrical contact with each other. The term “coupled” may mean that two or more elements are in direct physical or electrical contact. However, “coupled” may also mean that two or more elements are not in direct contact with each other, but yet still co-operate or interact with each other. For example, “coupled” may mean that two or more elements do not contact each other but are indirectly joined together via another element or intermediate elements.

As used herein, the terms “on,” “overlying,” and “over” may be used in the following description and claims. “On,” “overlying,” and “over” may be used to indicate that two or more elements are in direct physical contact with each other. However, “over” may also mean that two or more elements are not in direct contact with each other. For example, “over” may mean that one element is above another element but the two elements are not in contact with each other and may have another element or elements in between. It should be noted that “overlying” and “over” are relative terms that include regions located beneath a substrate when the substrate is turned upside down.

As used herein, the term “group III” elements indicates the elements found in what is commonly referred to as group III of the periodic table. For example, boron (B), aluminum (Al), gallium (Ga), and indium (In) are group III elements. Similarly, the term “group V” elements indicates the elements found in what is commonly referred to as group V of the periodic table. For example, nitrogen (N), phosphorus (P), arsenic (As), antimony (Sb), and bismuth (Bi) are group V elements.

A first aspect of the present invention are intermediate band solar cells (IBSC) comprising an absorbing region having three or more energy levels including a valence band, one or more intermediate bands, and a conduction band. The one or more intermediate bands of the absorbing region are at energies between those of the valence band and the conduction band.

In some embodiments, the solar cells further comprise a hole extraction region having a valence band and a conduction band; and an electron extraction region having a valence band and a conduction band. In these embodiments, the absorbing region is formed between the hole extraction region and the electron extraction region, the one or more intermediate bands are thermally isolated from the valence and conduction band in the absorbing region as well as from the conduction band in the hole and electron extraction regions, the intermediate bands are partially populated by free carriers, and the conduction band offset between the absorbing region and electron extraction region and the valence band offset between the absorbing region and hole extraction region are sufficiently small to permit easy transport of carriers across these interfaces. In some embodiments, the solar cell further comprises an upper confining region formed over the absorbing region.

In some embodiments, an intermediate band in the absorbing region is lower in energy than the conduction band in the electron extraction region, and the difference in energies of the two bands is greater than about 0.0768 eV; preferably greater than about 0.3072 eV; more preferably greater than about 0.4608 eV. In some embodiments, an intermediate band in the absorbing region is lower in energy than the conduction band in the hole extraction region, and the difference in energies of the two bands is greater than about 0.0768 eV; greater than about 0.3072 eV; more preferably greater than about 0.4608 eV.

In some embodiments, the conduction band of the absorbing region is lower in energy than the conduction band of the electron extraction region, and the difference in energies of the two bands is less than about 0.1536 eV; preferably less than about 0.0768 eV. In more preferred embodiments, the conduction band of the absorbing region is about the same or higher in energy than the conduction band of the electron extraction region.

In some embodiments, the valence band of the absorbing region is higher in energy than the valence band of the hole extraction region, and the difference in energies of the two bands is less than about 0.1536 eV; preferably less than about 0.0768 eV. In more preferred embodiments, the valence band in the absorbing region is about the same or higher in energy than the valence band in the hole extraction region.

Exemplary IBSCs of the present invention, as presented herein, are described as having an internal structure comprising one or more regions. These regions are not meant to be limited to being single regions, but may be formed of multiple subregions, which may be of similar or distinct compositions. Further, the IBSCs of embodiments of the present invention may comprise additional regions or regions that may be formed over or under the IBSC structure described above, or additional regions or regions may be formed in between the regions described herein.

In some embodiments, the IBSC may further comprise a substrate, over which may be formed a buffer region, over which is formed the remainder of the solar cell structure. In related embodiments, the IBSC may further comprise a back electrical contact formed on a side of the substrate opposite the hole extraction region and a front electrical contact formed over the electron extraction region on a side of the device opposite the substrate. In some embodiments, the buffer region and the hole extraction region may comprise one region.

In some embodiments, the substrate comprises an n-type substrate, the buffer region comprises an n-type buffer region, the hole electron extraction region comprises an n-type hole extraction region and the electron extraction region comprises a p-type electron extraction region. In some embodiments, the absorbing region comprises a dilute nitride semiconductor region comprising AlₙInₘGa₁₋ₙ₋ₘN_{c}AsᵥSbₖP_{1-c-v-k} where 0≦n, m, v, k≦1 and 0.001<c<0.2; preferably the composition of the absorbing region is selected such that the absorbing region has a bandgap between an intermediate band of the absorbing region and either the valence band or the conduction band of the absorbing region is in the range of about 1.3 eV to about 1.6 eV, more preferably in the range of about 1.4 eV to about 1.5 eV and a total bandgap in the range of about 2.2 eV to about 2.5 eV, more preferably in the range of about 2.3 eV to about 2.4 eV. In some embodiments of this aspect, the substrate may comprise GaP. In some embodiments of this aspect, the n-type buffer region and the n-type hole extraction region may comprise one region.

In some embodiments, the substrate comprises n-type GaP; the hole extraction region comprises n-type GaAsₓP₁₋ₓ where 0.35<x<0.6, preferably 0.4<x<0.54; the absorbing region comprises n-type GaAsₓN_{c}P_{1-x-c} where 0.005<c<0.2, preferably 0.015<c<0.05 and 0.37<x<0.77, preferably 0.47<x<0.67; and the electron extraction region comprises p-type GaP.

In other embodiments, methods of fabricating an IBSC are presented. These methods comprise a epitaxially growing an absorbing region has three or more energy levels including a valence band, one or more intermediate bands, and a conduction band; wherein said one or more intermediate bands are at energies between those of the valence band and the conduction band. In these embodiments, the absorbing region has three or more energy levels including a valence band, one or more intermediate bands, and a conduction band; wherein said one or more intermediate bands are at energies between those of the valence band and the conduction band.

In some embodiments, the methods further comprise epitaxially growing a hole extraction region; and epitaxially growing an electron extraction region; wherein said absorbing region is epitaxially grown between said hole extraction region and said electron extraction region, the one or more intermediate bands of the absorbing region are thermally isolated from the valence and conduction band in the absorbing region as well as from the conduction band in the hole and electron extraction regions, the intermediate bands are partially populated by free carriers, and the conduction band offset between the absorbing region and electron extraction region and the valence band offset between the absorbing region and hole extraction region are sufficiently small to permit easy transport of carriers across these interfaces.

In some embodiments, the methods further comprise forming a back electrical contact on a side of the substrate opposite the absorbing region; and forming a front electrical contact on a side of the device opposite the substrate. In these methods, the epitaxially grown absorbing region has a valence band, an intermediate band and a conduction band, wherein the intermediate band has an energy level between that of the valence band and the conduction band and the intermediate band is thermally isolated from the valence and conduction band in the absorbing region as well as from the conduction band in the hole and electron extraction regions. The intermediate band may also be partially populated by free carriers in order to efficiently absorb photons over a wide range of energies from both valence band to intermediate band and simultaneously intermediate band to upper conduction band and wherein the band offset between the conduction band of the absorbing region and electron extraction region and the band offset between the valence band of the absorbing region and hole extraction region are sufficiently small to permit easy transport of carriers across these interfaces.

In some embodiments, the intermediate band in the absorbing region is lower in energy than the conduction band in the electron extraction region, and the difference in energies of the two bands is greater than about 0.0768 eV; preferably greater than about 0.3072 eV; more preferably greater than about 0.4608 eV. In some embodiments, an intermediate band in the absorbing region is lower in energy than the conduction band in the hole extraction region, and the difference in energies of the two bands is greater than about 0.0768 eV; preferably greater than about 0.3072 eV; more preferably greater than about 0.4608 eV.

In some embodiments, the conduction band of the absorbing region is lower in energy than the conduction band of the electron extraction region, and the difference in energies of the two bands is less than about 0.1536 eV; preferably less than about 0.0768 eV. In preferred embodiments, the conduction band of the absorbing region is about the same or higher in energy than the conduction band of the electron extraction region.

In some embodiments, the valence band of the absorbing region is higher in energy than the valence band of the hole extraction region, and the difference in energies of the two bands is less than about 0.1536 eV; preferably less than about 0.0768 eV. In preferred embodiments, the valence band in the absorbing region is about the same or higher in energy than the valence band in the hole extraction region.

In some embodiments, the methods may further comprise epitaxially growing a buffer region over the substrate, over which is formed a remaining solar cell structure. In some embodiments of this aspect, methods of fabricating an IBSC may further comprise forming a contact region over the electron extraction region. In some embodiments of this aspect, methods of fabricating an IBSC may further comprise forming a back electrical contact on a side of the substrate opposite the hole extraction region and forming a front electrical contact over the electron extraction region on a side of the device opposite the substrate.

In some embodiments, the substrate comprises a n-type substrate, the hole electron extraction region comprises an n-type hole extraction region and the electron extraction region comprises a p-type electron extraction region.

In some embodiments, the absorbing region comprises a dilute nitride semiconductor region comprising AlₙInₘGa₁₋ₙ₋ₘN_{c}AsᵥSbₖP_{1-c-v-k} where 0≦n, m, v, k≦1 and 0.001<c<0.2; preferably the composition of the absorbing region is such that a bandgap between an intermediate band of the absorbing region and either the valence band or the conduction band of the absorbing region is in the range of about 1.3 eV to about 1.6 eV, more preferably in the range of about 1.4 eV to about 1.5 eV, and a total bandgap in the range of about 2.2 eV to about 2.5 eV, more preferably in the range of about 2.3 eV to about 2.4 eV. In some embodiments, the substrate comprises GaP.

In some embodiments, the substrate comprises n-type GaP, the hole extraction region comprises n-type GaAsₓP₁₋ₓ where 0.35<x<0.6, preferably 0.4<x<0.54; the absorbing region comprises n-type GaAsₓN_{c}P_{1-x-c} where 0.005<c<0.2, and 0.37<x<0.77, preferably 0.015<c<0.05 and 0.47<x<0.67; and the electron extraction region comprises p-type GaP.

Other embodiments of the present invention are solar cells comprising a dilute nitride absorbing region located between a hole extraction region and an electron extraction region, wherein a bandgap between an intermediate band of the absorbing region and either the valence band or the conduction band of the absorbing region is in the range of about 1.3 eV to about 1.6 eV; an overall bandgap of the absorbing region is in the range of about 2.2 eV to about 2.5 eV; the bandgap between the conduction band in the absorbing region and the conduction band in the electron extraction region is less than about 0.1536 eV; and the bandgap between the valence band in the absorbing region and the valence band in the hole extraction region is less than about 0.1536 eV.

In some of these embodiments, the dilute nitride absorbing layer comprises GaAsₓN_{c}P_{1-x-c} where 0.005<c<0.2, and 0.37<x<0.77; a bandgap between an intermediate band of the absorbing region and either the valence band or the conduction band of the absorbing region is in the range of about 1.4 eV to about 1.5 eV; an overall bandgap of the absorbing region is in the range of about 2.3 eV to about 2.4 eV; and the solar cell has a theoretical efficiency of greater than 55%.

In the above described embodiments, only the absorbing region is described as comprising dilute nitride semiconductor materials. However, this is not a limitation of the present invention, and any other region of an IBSC of the present invention may comprise a dilute nitride semiconductor material.

In the above described embodiments, the absorbing region may be formed over the hole extraction region and the electron extraction region may be formed over the absorbing region. In other embodiments, the absorbing region may be formed over the electron extraction region and the hole extraction region may be formed over the absorbing region.

In some embodiments, the hole extraction region and the electron extraction region may have the same or substantially the same bandgap, however this is not a limitation of the present invention and in other embodiments, the hole extraction region and electron extraction region may have different bandgaps. In some embodiments, the hole extraction region and the electron extraction region may have the same or substantially the same composition, however this is not a limitation of the present invention and in other embodiments, the hole extraction region and electron extraction region may have different compositions.

Embodiments of the present invention comprise doped and undoped semiconductor regions. While some of the examples provided herein are for uniformly doped regions, this is not a limitation of the present invention and in other embodiments, the doping levels of one or more regions may vary as a function of depth or extent, or one or more regions may be doped with more than one doping element.

In some embodiments, the defect density in the absorbing region may be sufficiently low as to not adversely affect the performance of the IBSC. This means that the dislocation density within the absorbing region may be less than about 1×10⁸ cm⁻², preferably less than about 1×10⁷ cm⁻², preferably less than about 1×10⁶ cm⁻². In some embodiments, the defect density in the absorbing region, the electron extraction region, and the hole extraction region may be sufficiently low as to not adversely affect the performance of the IBSC. In these embodiments, all three regions may have appropriately low dislocation densities.

As used herein, the term “absorbing region” or “absorption region” means the region in a solar cell where a portion of the solar spectrum with photons having an energy greater than the bandgap of the active region in the solar cell are captured or absorbed. Upon capture or absorption of a photon, an electron-hole pair is created that produces a DC current under the action of an electric field. The conversion efficiency for a single junction cell may have a peak near the bandgap of the active region and may decrease rapidly for higher and lower energies. Generally, the absorbing region makes up one region of an active region of a solar cell structure.

As used herein, the term “band offset” means the difference between two band energies.

As used herein, “kT” represents the product of the Boltzmann constant, k, and temperature, T. This product generally indicates the thermal energy of a system. kT at 25° C. is about 0.0256 eV.

As used herein, the term “about” means in reference to a quantitative value refers to the indicated value plus or minus 10%.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components.

FIG. 1A-1C illustrate the electronic structure of different types of solar cells;

FIG. 2 is a schematic illustration of an energy band diagram of an exemplary intermediate band solar cell (IBSC) embodiment of the present invention;

FIG. 3 is a cross-sectional view of a semiconductor structure in accordance with an embodiment of the present invention;

FIG. 4 is a cross-sectional view of a semiconductor structure in accordance with an embodiment of the present invention;

FIG. 5 is a schematic illustration of an energy band diagram of the semiconductor structure in FIG. 4;

FIG. 6 is a plot of solar cell efficiency as a function of intermediate bandgap and total bandgap energy;

FIG. 7 is a flow diagram summarizing methods of fabricating solar cells in accordance with embodiments of the present invention;

For simplicity of illustration and ease of understanding, elements in the various figures are not necessarily drawn to scale, unless explicitly so stated. Further, if considered appropriate, reference numerals have been repeated among the figures to indicate corresponding and/or analogous elements. In some instances, well-known methods, procedures, components and circuits have not been described in detail so as not to obscure the present disclosure. The following detailed description is merely exemplary in nature and is not intended to limit the disclosure of this document and uses of the disclosed embodiments. Furthermore, there is no intention that the appended claims be limited by the title, technical field, background, or abstract.

### DETAILED DESCRIPTION OF THE INVENTION

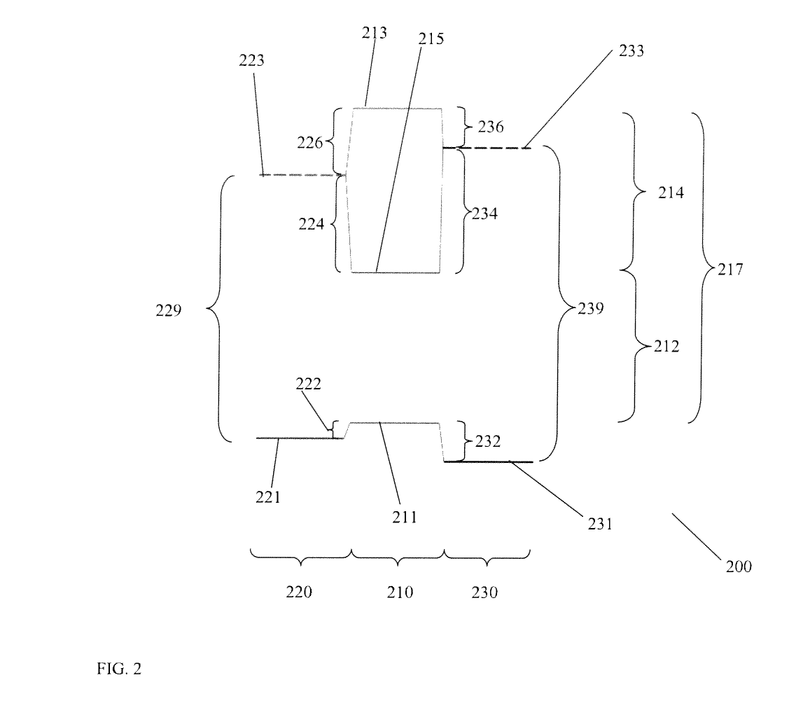

FIG. 2 shows a schematic energy band diagram of the active region of an exemplary IBSC (200) embodiment of the present invention. The active region of an IBSC comprises an absorbing region 210, an electron extraction region 230 and a hole extraction region 220. Hole extraction region 220 comprises a material with a bandgap 229, a valence band 221 and a conduction band 223. Absorbing region 210 comprises a material with a valence band 211, an intermediate band 215, and a conduction band 213. Electron extraction region 230 comprises a material with a bandgap 239, a valence band 231 and a conduction band 233. The IBSC 200 has a valence band offset 222 between absorbing region 210 and hole extraction region 220 and a valence band offset 232 between absorbing region 210 and electron extraction region 230. The IBSC 200 also has a conduction band offset 224 between conduction band 223 of hole extraction region 220 and intermediate band 215 of absorbing region 210, a conduction band offset 226 between conduction band 223 of hole extraction region 220 and conduction band 213 of absorbing region 210, a conduction band offset 234 between conduction band 233 of electron extraction region 230 and intermediate band 215 of absorbing region 210, and a conduction band offset 236 between conduction band 233 of electron extraction region 230 and conduction band 213 of absorbing region 210. Absorbing region 210 has three associated energy bands: E1 (212) from valence band 211 to intermediate band 215; E2 (214) from intermediate band 215 to conduction band 213; and the overall energy gap (217), also called the bandgap of absorbing region 210, from valence band 211 to conduction band 213. Note that the sum of E1 (212) and E2 (214) equals the bandgap 217 of absorbing region 210. The schematic in FIG. 2 is not meant to represent a complete IBSC 200, but only instead represents the active region of an IBSC 200.

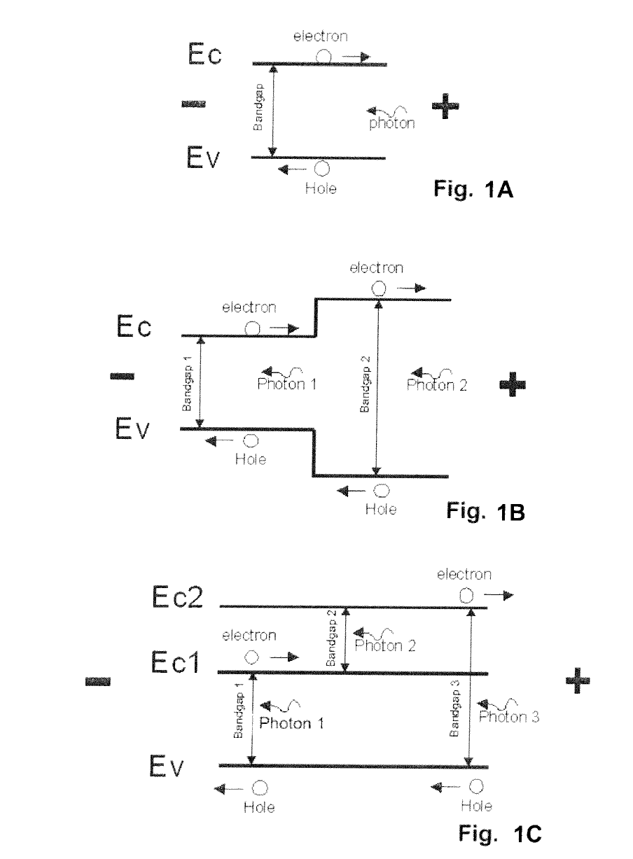

In operation, a portion of the incident solar radiation is absorbed in absorption region 210. As discussed with reference to FIG. 1, three energy transitions are possible, which increases the fraction of solar radiation that can be absorbed, relative to a single or dual junction solar cell. Absorbed solar photons create electron-hole pairs. Electrons are collected through electron extraction region 230 and holes are collected through hole extraction region 220.

An ISBC of the present invention meets several specific criteria that can be described with reference to FIG. 2. First, an intermediate band 215 of absorbing region 210 must be lower in energy than the conduction bands of electron extraction region 230 and hole extraction region 220 with band offsets 224 and 234 sufficiently large to thermally isolate carriers in the intermediate band 215 from the adjacent conduction bands 220 and 230. In some embodiments, these band offsets may be larger than about 3kT (i.e., about 0.0768 eV at 25° C.); preferably larger than about 12kT (i.e., about 0.3072 eV at 25° C.); preferably larger than about 18kT (i.e., about 0.4608 eV at 25° C.).

Second, conduction band 213 of absorbing region 210 may be higher or lower in energy than the conduction band 233 of extraction region 230, but must not be so much lower than conduction band 233 of electron extraction region 230 so as to inhibit easy extraction of excited electrons from the absorbing region 210 to the electron extraction region 230. In some embodiments, the conduction 213 of absorbing region 210 is lower in energy than the conduction band 233 of electron extraction region 230 with a band offset 236 less than about 6kT (i.e., about 0.1536 eV at 25° C.); in these embodiments, the band offset 236 is preferably less than about 3kT (i.e., about 0.0768 eV at 25° C.). In preferred embodiments, the conduction band 213 of absorbing region 210 is higher in energy than the conduction band 233 of extraction region 230. The exemplary electronic structure shown in FIG. 2 demonstrates an example where the conduction band 213 of absorbing region 210 is higher in energy than the conduction band 233 of extraction region 230.

Third, the valence band 211 of absorbing region 210 may be lower or higher in energy than the valence band 221 of hole extraction region 220, but must not be so much higher than valence band 221 of hole extraction region 220 so as to inhibit easy extraction of holes from the absorbing region 210 to the hole extraction region 220. In some embodiments, the valence band 211 of absorbing region 210 may be higher in energy than the valence band 221 of hole extraction region 220 with a band offset 222 less than about 6kT (i.e., about 0.01536 eV at 25° C.); in these embodiments, the band offset 236 is preferably less than about 3kT (i.e., about 0.0768 eV at 25° C.). In preferred embodiments, the valence band 211 of absorbing region 210 is lower in energy than the valence band 221 of hole extraction region 220. The exemplary electronic structure shown in FIG. 2 demonstrates an example where the valence band 211 of absorbing region 210 higher in energy than the valence band 221 of hole extraction region 220, but the band offset 222 is relatively small.

Fourth, the position of intermediate band 215 should be optimized to provide maximum power by current matching the separate portions of the absorbed solar spectrum. This may be accomplished by matching the total number of photons absorbed at or near energy transition E1 (shown as 212 in FIG. 2) with the total number of photons absorbed at or near energy E2 (shown as 214 in FIG. 2). Each of these photon numbers is dependent upon the actual solar spectrum incident upon the device, which may have different photon numbers at different energies and may vary from location to location.

Fifth, an intermediate band 215 should be partially populated by free carriers in order to efficiently absorb photons over a wide range of energies from the energy transitions between the conduction, valence, and intermediate band or bands in absorbing region 210. These correspond to energy transitions E1, E2, and the bandgap of the absorbing region (E1+E2, shown as 217 in FIG. 2). In some embodiments, this may be achieved by doping absorption region 210 with an appropriate number of dopant atoms. The doping level may be such that the resulting Fermi level is at an energy about midway between intermediate band 215 and conduction band 213 of absorption region 210. In some embodiments, the dopant atoms may comprise donor dopant atoms.

In some embodiments of the present invention, the defect density in the absorbing region may be sufficiently low as to not adversely affect the performance of the IBSC. In some embodiments, the dislocation density may be less than about 1E8 cm⁻²; preferably less than about 1E7 cm⁻²; preferably less than about 1E6 cm⁻².

In some embodiments of the present invention, the defect density in the absorbing region, the electron extraction region, and the hole extraction region may be sufficiently low as to not adversely affect the performance of the IBSC. In some embodiments, the dislocation density may be less than about 1E8 cm⁻²; preferably less than about 1E7 cm⁻²; preferably less than about 1E6 cm⁻².

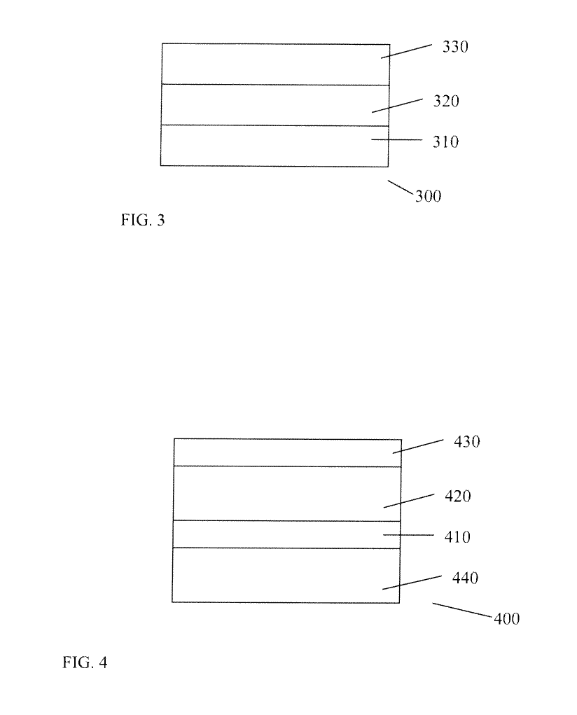

FIG. 3 is a cross-sectional view of semiconductor structure 300 in accordance with an embodiment of the present invention. Semiconductor structure 300 comprises a hole extraction region 310, an absorbing region 320 formed over hole extraction region 310 and an electron extraction region 330 formed over absorbing region 320.

Absorbing region 320 comprises an intermediate band as detailed in the discussion in reference to FIG. 2. The addition of a small fraction of highly electronegative atoms, such as nitrogen, into a host semiconductor material has been shown to dramatically alter the band-structure of the host material by splitting the conduction band into two sub-bands. Because of the interaction between the two sub-bands, one sub-band is pushed to energy higher than the band-gap of the host semiconductor, and the other to a lower energy, thereby creating an additional energy level in the band structure. In particular, this has been applied to the dilute nitride material system. This material system comprises semiconductors based on gallium arsenide (GaAs) or gallium phosphide (GaP) into which a relatively small amount of N has been added. Examples of such materials include InGaNAs, GaNAs, GaNP, and GaNAsP. In some embodiments of the present invention, absorbing region 320 may comprise a dilute nitride semiconductor region comprising AlₙInₘGa₁₋ₙ₋ₘN_{c}AsᵥSbₖP_{1-c-v-k} where 0≦n, m, v, k≦1 and 0.001<c<0.3.

In some embodiments of the present invention, absorbing region 320 may comprise AlₙInₘGa₁₋ₙ₋ₘN_{c}AsᵥSbₖP_{1-c-v-k} where 0≦n, m, v, k≦1 and 0.001<c<0.2. One skilled in the art would readily recognize that for dilute nitride semiconductors with this general formula, 0≦n+m≦1, 0.001<c<0.2, and 0.001<v+k+c≦1. Specific examples of materials fitting this formula that may be used in embodiments of the present invention include InₘGa₁₋ₘN_{c}P_{1-c} (0.001<c<0.2 and 0≦m≦1), GaN_{c}AsᵥP_{1-c-v} (0.001<c<0.2 and 0≦v≦1), GaN_{c}P_{1-c} (0.001<c<0.2), and GaN_{c}AsᵥSbₖP_{1-c-v-k} (0.001<c<0.2, and 0≦v, k≦1). However, these examples are not meant to be limitations of the present invention and in other embodiments the absorbing region 320 may comprise AlₙInₘGa₁₋ₘ₋ₙN_{c}AsᵥSbₖP_{1-c-v-k} where 0≦n, m, v, k≦1 and 0.001<c<0.2; that is n and m may individually have a value in the range of 0 to 1 so long as the sum of the n and m does not exceed 1, and v and k may individually have any value in the range of 0 and 0.999 so long as the sum of c, v, and k does not exceed 1, with preferably 0.01<c<0.05.

Preferably the composition of absorbing region 320 may be controlled to have an intermediate bandgap in the range of about 1.3 eV to about 1.6 eV (212 or 214 in FIG. 2), more preferably in the range of about 1.4 eV to about 1.5 eV, and a total bandgap (217 in FIG. 2) in the range of about 2.2 eV to about 2.5 eV, more preferably in the range of about 2.3 eV to about 2.4 eV. Thus, referring to FIG. 2, preferably one intermediate band gap 212 or 214 is preferably in the range of range of about 0.6 eV to about 1.2 eV; more preferably in the range of about 0.8 to about 1.0 eV. In some embodiments of this aspect, electron extraction region 330 may comprise an p-type electron extraction region and hole extraction region 310 may comprise an n-type hole extraction region.

FIG. 4 is a cross-sectional view of semiconductor structure 400 in accordance with another embodiment of the present invention. Semiconductor structure 400 comprises a substrate 440, a GaAsₓP₁₋ₓ where 0.35<x<0.6, preferably 0.4<x<0.54, buffer region 410, which also may serve the function of the hole extraction region described above, formed over substrate 440, a GaAsₓN_{c}P_{1-x-c} where 0.005<c<0.2 and 0.37<x<0.77, preferably 0.015<c<0.05 and, 0.47<x<0.67 absorbing region 420 formed over buffer region 410 and a GaP electron extraction region 430 formed over absorbing region 420. In semiconductor structure 400, electrons generated in absorbing region 420 are extracted through electron extraction region 430 and the holes are extracted from absorbing region 420 into buffer region 410 towards substrate 440. In some embodiments of this aspect, the substrate may comprise a n-type substrate, the buffer region may comprise an n-type buffer region and the electron extraction region may comprise a p-type electron extraction region. In some embodiments of this aspect, substrate 440 may comprise GaP, AlP, AlGaAs, GaAsP, or ZnSe, GaAs, InP or Si, however this is not meant to be a limitation of the present invention and in other embodiments, substrate 440 may comprise any material. It should be noted that additional regions may also be formed below, between, and/or above the above described regions.

Examples of dopants that may be used for doped regions include Zn or C as p-type dopants and Si, Se, or Te as an n-type dopant, although other dopants may be used in other embodiments.

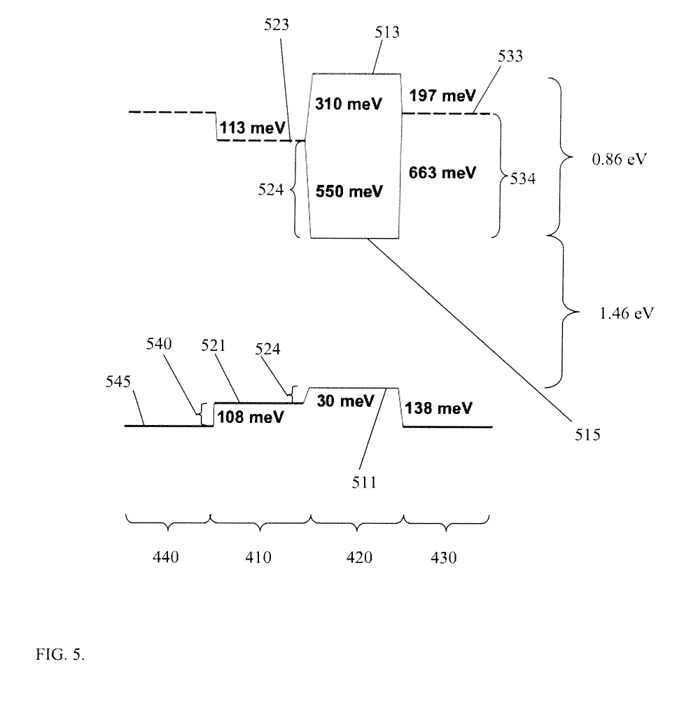

FIG. 5 shows the band structure for a specific example of an embodiment of the present invention wherein substrate 440 comprises n-type GaP, buffer region 410 comprises n-type GaAsₓP₁₋ₓ, where x is about 0.47, absorbing region 420 comprises n-type GaN_{c}AsₓP₁₋ₓ where c is about 0.23 and x is about 0.577, and electron extraction region 430 comprises p-type GaP. The energy level of intermediate band 515 in absorption region 420 was estimated based on the band anticrossing model.

Intermediate band 515 in absorbing region 420 is about 1.46 eV above valence band 511 (corresponding to E1 (212 in FIG. 2)) and about 0.86 eV below conduction band 513 (corresponding to E2 (214 in FIG. 2)). Band offset 524 between intermediate band 515 of absorbing region 420 and conduction band 523 of buffer region 410 is about 550 meV and band offset 534 between intermediate band 515 and conduction band 533 of electron extraction region 430 region is about 663 meV. These large values, compared to the thermal energy (kT) of about 26 meV at room temperature insure that intermediate band 515 is thermally isolated from both buffer region 410 and electron extraction region 430. In other words, carriers in the intermediate band cannot escape from the intermediate band as a result of their thermal energy alone.

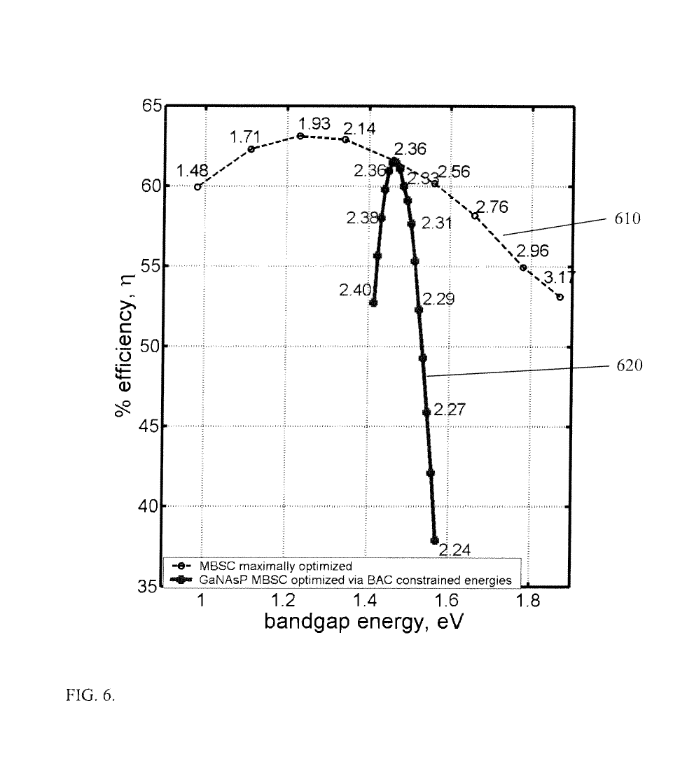

The position of intermediate band 515 has been optimized to maximize the fraction of the solar spectrum that is collected in the three absorption transitions to achieve the highest efficiency. FIG. 6 shows the efficiency of the IBSC of FIG. 4 as a function of intermediate and conduction bandgap energy. The curve labeled 610 (open circles) shows the solar cell efficiency as a function of intermediate bandgap energy for the ideal case where the band energies may be tuned independently. The numbers over the curve indicate the total bandgap energy while the value on the x-axis is that for the intermediate band. From this curve it would appear that there is a broad range of bandgaps that could produce high efficiency solar cells.

However, in most material systems, and in particular for the case of GaNAsP, it is not possible to independently tune the band energies, thus adding one more constraint to the realization of a high efficiency IBSC. For the case of GaNAsP and for dilute nitride or isolectronic IBSCs in general, the two band energies are not completely independent but are instead coupled. This results in a relatively narrow window of energies that may be used to achieve high efficiency. Curve 620 (filled squares) in FIG. 6 shows the efficiency as a function of intermediate bandgap energy for the specific case of the GaNAsP cell with a phosphorus content of 0.4. In this case in order to achieve a theoretical efficiency of at least 55%, the allowable intermediate band energies must be with the range of about 1.42 eV to about 1.50 eV and the total bandgap energy must be within the range of about 2.30 eV to about 2.39 eV.

Referring back to FIG. 5, for an IBSC with these particular band energies, once electrons are in conduction band 513 of absorbing region 420 they are easily extracted into electron extraction region 430 because conduction band 513 in absorbing region 420 is higher in energy than conduction band 533 of electron extraction region 430 by about 197 meV.

Again referring to FIG. 5, holes are also easy to extract from valence band 511 of absorbing region 420 as valence band offset 524 between valence band 511 of absorbing region 420 and valence band 521 of buffer region 410 is only about 30 meV, which is on the order of kT at 25° C. The holes face a second barrier of about 108 meV at the buffer region/substrate interface (valence band offset 540 between valence band 521 of buffer region 410 and valence band 545 of substrate 440), which may also be relatively easily surmounted at room temperature.

In one embodiment, the thickness of substrate 440 may be in the range of about 25 μm to about 400 μm, however this is not meant to be a limitation of the present invention and in other embodiments substrate 440 may have any thickness.

In one embodiment of the present invention buffer region 410 may have a thickness in the range of about 0.05 μm to about 5 μm. The large range in thickness in part depends on the functions required of the buffer region. If it is functioning mainly as a hole extraction region, then the thickness may be relatively smaller, for example in the range of about 0.05 μm to about 1 μm, preferably in the range of about 0.1 μm to about 0.5 μm. However, if the buffer region also acts to help improve the quality of the subsequently formed absorption region, then the thickness may be relatively larger. The buffer region may be doped or undoped. In one embodiment, the buffer region may be doped with the same conductivity type as that of the substrate. In the example given above, the buffer region may be doped n-type and may have a carrier concentration in the range of about 1×10¹⁷ cm⁻³ to about 3×10¹⁸ cm⁻³.

In one embodiment of the present invention absorption region 420 may have a thickness in the range of about 1 μm to about 6 μm, more preferably in the range of about 2 μm to about 4 μm. The absorption region may be doped or undoped. In one embodiment, the absorption region may be doped with the same conductivity type as that of the buffer region. In the example given above, the absorption region may be doped n-type and may have a carrier concentration in the range of about 5×10¹⁶ cm⁻³ to about 5×10¹⁷ cm⁻³.

In one embodiment of the present invention, electron extraction region 430 may have a thickness in the range of about 0.01 μm to about 1 μm, more preferably in the range of about 0.02 μm to about 0.2 μm. The electron extraction region may be doped or undoped. In one embodiment the electron extraction region may be doped with the opposite conductivity type as that of the absorption region. In the example given above, the electron extraction region may be doped p-type and may have a carrier concentration in the range of about 1×10¹⁷ cm⁻³ to about 3×10¹⁸ cm⁻³.

In one embodiment of the present invention, buffer region 410 (shown in FIG. 4) may act to reduce dislocations in subsequently formed regions. The composition of the absorbing region in an IBSC may not be lattice matched, or may be substantially lattice matched to any commercially available substrate. Solar cells require a relatively thick region (a few hundred nanometers to a few microns thick) in order to absorb a high percentage of incident photons. Even a relatively small lattice mismatch between the absorption region and the substrate will exceed the critical thickness and result in the formation of threading and misfit dislocations. Such dislocations may become centers for carrier recombination, dramatically reducing the efficiency of a solar cell device.

In one embodiment of the present invention the defect density in the absorbing region may be sufficiently low as to not adversely affect the performance of the IBSC. In some embodiments, the dislocation density in the absorbing region may be less than 1×10⁸ cm⁻²; preferably less than 1×10⁷ cm⁻²; preferably less than 1×10⁶ cm⁻².

In the embodiment of the present invention where the absorption region comprises GaNₓAs_{y}P_{1-x-y}, the amount of N and As (i.e., x and y) necessary to create a desired multi-band structure, as discussed above, results in a large lattice mismatch between the GaNₓAs_{y}P_{1-x-y} region and commercially available substrates (e.g. GaAs, GaP, InP). In a specific embodiment, the absorption region may comprise GaNₓAs_{y}P_{1-x-y} where x is about 0.02 and y is about 0.58. In this embodiment, the substrate may comprise GaP. Corresponding free-standing lattice constants for the absorption region material and the substrate are about 5.5494 Å, and about 5.4505 Å, respectively, which creates a lattice mismatch of about 1.8%. The required thickness of the absorption region is in excess of the critical thickness for such a mismatch (typically in the range of few hundred angstroms). Thus, growth of such a thick region of GaNₓAs_{y}P_{1-x-y} directly on a GaP substrate, will exceed the critical thickness, resulting in the formation of threading and misfit dislocations.

Some embodiments of the present invention comprise a metamorphic buffer region formed over a substrate prior to formation of the absorption region. In some of these embodiments, the metamorphic buffer region may be lattice-matched to the overlying GaNₓAs_{y}P_{1-x-y} absorbing region. In other embodiments, the buffer region may be graded in lattice constant. For example, in some embodiments, the average lattice constant of the buffer region may be equal to the lattice constant of the GaNₓAs_{y}P_{1-x-y}. In other embodiments, the lattice constant at the top of the buffer region may be equal to the lattice constant of the overlying GaNₓAs_{y}P_{1-x-y}. Metamorphic buffer regions may have a constant composition or may be continuously or step graded. However, this is not meant to be limiting and in other embodiments of the present invention the buffer region may comprise more than one region or may comprise more than one material and the materials may vary in composition in any way. The metamorphic buffer region is designed to release the strain from lattice mismatch to the substrate before the growth of the absorption region. In other words the buffer region may relax to the lattice constant of the desired subsequently grown absorption region. In addition, it may also prevent the propagation of a substantial number of dislocations into that subsequently grown absorption region.

In embodiments which contain a constant composition metamorphic buffer region formed over a GaP substrate, the buffer region may comprise GaAsP. In one embodiment, semiconductor structure 400 of FIG. 4 may comprise n-type GaP substrate 440, n-type GaAsₓP₁₋ₓ where x is about 0.47 buffer region 410 formed over n-type GaP substrate 440, n-type GaN_{c}AsₓP₁₋ₓ where c is about 0.23 and x is about 0.577 n-type absorption region formed over n-type GaAsₓP₁₋ₓ where x is about 0.47 buffer region 410 and p-type GaP electron extraction region 430. In this embodiment the concentrations of the elements in GaAsP buffer region 410 and in GaNAsP absorbing region 420 are chosen such that these two regions are lattice matched or substantially lattice matched and the lattice constant is about 5.546 Å.

Embodiments of the present invention comprise doped and undoped semiconductor regions. While some of the examples provided herein describe utilization of uniformly doped regions, this is not a limitation of the present invention and in other embodiments, the doping levels of one or more regions may vary as a function of depth or extent, or one or more regions may be doped with more than one doping element.

In the above described embodiments, only the absorbing region is described as comprising dilute nitride semiconductor materials. However, this is not a limitation of the present invention, and any other region of an IBSC of the present invention may comprise a dilute nitride semiconductor material.

In the above described embodiments, the absorption region may be formed over the hole extraction region and the electron extraction region may be formed over the absorption region. In other embodiments, the absorption region may be formed over the electron extraction region and the hole extraction region may be formed over the absorption region.

In some embodiments the hole extraction region and the electron extraction region may have the same or substantially the same bandgap, however this is not a limitation of the present invention and in other embodiments the hole extraction region and electron extraction region may have different bandgaps. In some embodiments, the hole extraction region and the electron extraction region may have the same or substantially the same composition, however this is not a limitation of the present invention and in other embodiments the hole extraction region and electron extraction region may have different compositions.

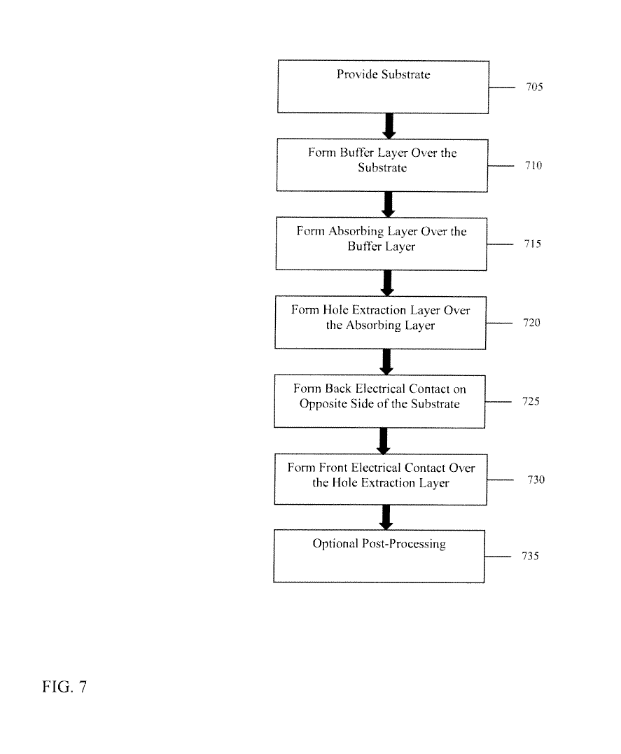

The method of making an IBSC described generally in connection with FIG. 4 above is summarized with a flow diagram in FIG. 7. In this flow diagram, certain specific steps are indicated with boxes shown in a particular order, but this is not intended to be limiting. In some instances, additional steps not explicitly indicated may be performed, some of the indicated steps may be omitted, or some steps may be performed simultaneously or in a different order than that shown in FIG. 7.

In the flow diagram in FIG. 7, fabrication of the ISBC begins at block 705 by providing a substrate. Over the substrate, a buffer region is formed at block 710, permitting an absorbing region to be formed over the buffer region at block 715. The hole extraction region is formed over the absorbing region at block 720.

A back electrical contact may be formed on the opposite side of the substrate at block 725 and a front electrical contact may be formed over the hole extraction region at block 730. Any optional post-processing of the IBSC, for example surface roughening or application of an anti-reflective coating, may be done within the process flow or post-process at block 735.

The above described configuration of electrical contacts is not meant to be limiting. In other embodiments of the present invention, electrical contacts may be mounted in other configurations.

Formation of the regions comprising the IBSC may be performed using a variety of crystal growth techniques well known in the art, for example molecular beam epitaxy (“MBE”), metalorganic chemical-vapor-deposition (“MOCVD”), liquid phase epitaxy (“LPE”) or hydride vapor phase epitaxy (“HVPE”). Thus, in the preferred embodiments of the invention, the IBSC regions are deposited over a substrate, rather than being formed separately from the substrate and then bonded to the substrate. Preferably, the IBSC regions, including materials in the dilute nitride semiconductor absorbing region, are epitaxially grown over the substrate.

Formation of the contacts to the IBSC may be performed using a combination of patterning and deposition techniques. Patterning may be performed using photolithography processes or operations involve the use of masks and may sometimes be referred to as masking operations or acts. The photolithography process may include forming a region of a radiation-sensitive material, such as photoresist over the semiconductor structure, then exposing the photoresist using, for example, ultraviolet (“UV”) radiation to form a mask, and then using the pattern in the mask to transfer the pattern to a portion of the semiconductor structure. For example the pattern may be transferred by etching portions of the region or regions under the photoresist mask. When the photoresist mask is removed, the pattern remains in the underlying region or regions.

A variety of deposition techniques well known in the art may be used for formation of the contacts to the IBSC, for example evaporation, sputtering or printing. Examples of materials that may be used for contact formation include Au, Ge, Ni, Ti, W, Ag, but these examples are not meant to be limiting and in other embodiments other materials may be used for contact formation.

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A solar cell structure comprising:
an absorbing region having three or more energy levels including a valence band, one or more intermediate bands, and a conduction band; wherein said one or more intermediate bands are at energies between those of the valence band and the conduction band.

2. The solar cell structure of claim 1, wherein said active region further comprises:
a hole extraction region having a valence band and a conduction band; and
an electron extraction region having a valence band and a conduction band;
wherein said absorbing region is formed between said hole extraction region and said electron extraction region, the one or more intermediate bands are thermally isolated from the valence and conduction band in the absorbing region as well as from the conduction band in the hole and electron extraction regions, the intermediate bands are partially populated by free carriers, and the conduction band offset between the absorbing region and electron extraction region and the valence band offset between the absorbing region and hole extraction region are sufficiently small to permit easy transport of carriers across these interfaces.

3. The solar cell structure of claim 1, further comprising an upper confining region formed over the absorbing region.

4. The solar cell structure recited in claim 2, wherein an intermediate band in the absorbing region is lower in energy than the conduction band in the electron extraction region, and the difference in energies of the two bands is greater than about 0.0768 eV.

5. The solar cell structure recited in claim 2, wherein an intermediate band in the absorbing region is lower in energy than the conduction band in the electron extraction region, and the difference in energies of the two bands is greater than about 0.3072 eV.

6. The solar cell structure recited in claim 2, wherein an intermediate band in the absorbing region is lower in energy than the conduction band in the electron extraction region, and the difference in energies of the two bands is greater than about 0.4608 eV.

7. The solar cell structure recited in claim 2, wherein an intermediate band in the absorbing region is lower in energy than the conduction band in the hole extraction region, and the difference in energies of the two bands is greater than about 0.0768 eV.

8. The solar cell structure recited in claim 2, wherein an intermediate band in the absorbing region is lower in energy than the conduction band in the hole extraction region, and the difference in energies of the two bands is greater than about 0.3072 eV.

9. The solar cell structure recited in claim 2, wherein an intermediate band in the absorbing region is lower in energy than the conduction band in the hole extraction region, and the difference in energies of the two bands is greater than about 0.4608 eV.

10. The solar cell structure recited in claim 2, wherein the conduction band of the absorbing region is lower in energy than the conduction band of the electron extraction region, and the difference in energies of the two bands is less than about 0.1536 eV.

11. The solar cell structure recited in claim 2, wherein the conduction band of the absorbing region is lower in energy than the conduction band of the electron extraction region, and the difference in energies of the two bands is less than about 0.0768 eV.

12. The solar cell structure recited in claim 2, wherein the conduction band of the absorbing region is about the same or higher in energy than the conduction band of the electron extraction region.

13. The solar cell structure recited in claim 2, wherein the valence band of the absorbing region is higher in energy than the valence band of the hole extraction region, and the difference in energies of the two bands is less than about 0.1536 eV.

14. The solar cell structure recited in claim 2, wherein the valence band of the absorbing region is higher in energy than the valence band of the hole extraction region, and the difference in energies of the two bands is less than about 0.0768 eV.

15. The solar cell structure recited in claim 2, wherein the valence band in the absorbing region is about the same or higher in energy than the valence band in the hole extraction region.

16. The solar cell structure recited in claim 2, wherein a dislocation density within the absorbing region is less than about 1×10⁸ cm⁻².

17. The solar cell structure recited in claim 2, wherein a dislocation density within the absorbing region is less than about 1×10⁷ cm⁻².

18. The solar cell structure recited in claim 2, wherein a dislocation density within the absorbing region is less than about 1×10⁶ cm⁻².

19. The solar cell structure recited in claim 2, further comprising a substrate over which the solar cell structure is formed.

20. The solar cell structure recited in claim 19, further comprising a buffer region, wherein the buffer region is formed over the substrate and a remaining solar cell structure is formed over the buffer region.

21. The solar cell structure recited in claim 20, wherein the hole extraction region is the buffer region.

22. The solar cell structure recited in claim 19, further comprising a back electrical contact formed on a side of the substrate opposite the hole extraction region and a front electrical contact formed over the electron extraction region on a side of the device opposite the substrate.

23. The solar cell structure recited in claim 19, wherein the substrate comprises a n-type substrate, the hole electron extraction region comprises an n-type hole extraction region and the electron extraction region comprises a p-type electron extraction region.

24. The solar cell structure recited in claim 1, wherein the absorbing region comprises a dilute nitride semiconductor region comprising AlₙInₘGa₁₋ₙ₋ₘN_{c}AsᵥSbₖP_{1-c-v-k} where 0≦n, m, v, k≦1 and 0.001<c<0.2.

25. The solar cell structure recited in claim 2, wherein a bandgap between an intermediate band of the absorbing region and either the valence band or the conduction band of the absorbing region is in the range of about 1.3 eV to about 1.6 eV and an overall bandgap of the absorbing region is in the range of about 2.2 eV to about 2.5 eV.

26. The solar cell structure recited in claim 2, wherein a bandgap between an intermediate band of the absorbing region and either the valence band or the conduction band of the absorbing region is in the range of about 1.4 eV to about 1.5 eV and an overall bandgap of the absorbing region is in the range of about 2.3 eV to about 2.4 eV.

27. The solar cell structure recited in claim 19, wherein the substrate comprises n-type GaP, the hole extraction region comprises n-type GaAsₓP₁₋ₓ where 0.35<x<0.6, the absorbing region comprises n-type GaAsₓN_{c}P_{1-x-c} where 0.005<c<0.2, and 0.37<x<0.77 and the electron extraction region comprises p-type GaP.

28. The solar cell structure recited in claim 19, wherein the substrate comprises n-type GaP, the hole extraction region comprises n-type GaAsₓP₁₋ₓ where 0.4<x<0.54, the absorbing region comprises n-type GaAsₓN_{c}P_{1-x-c} where 0.015<c<0.05 and 0.47<x<0.67 and the electron extraction region comprises p-type GaP.

29. A method of fabricating a solar cell structure, comprising:
epitaxially growing an absorbing region over a substrate;
wherein the absorbing region has three or more energy levels including a valence band, one or more intermediate bands, and a conduction band; wherein said one or more intermediate bands are at energies between those of the valence band and the conduction band.

30. The method of claim 29, further comprising:
epitaxially growing a hole extraction region; and
epitaxially growing an electron extraction region;
wherein said absorbing region is epitaxially grown between said hole extraction region and said electron extraction region, the one or more intermediate bands of the absorbing region are thermally isolated from the valence and conduction band in the absorbing region as well as from the conduction band in the hole and electron extraction regions, the intermediate bands are partially populated by free carriers, and the conduction band offset between the absorbing region and electron extraction region and the valence band offset between the absorbing region and hole extraction region are sufficiently small to permit easy transport of carriers across these interfaces.

31. The method of claim 30, further comprising forming a back electrical contact on a side of the substrate opposite the hole extraction region; and forming a front electrical contact over the electron extraction region on a side of the device opposite the substrate.

32. The method of fabricating a solar cell structure recited in claim 30, wherein an intermediate band in the absorbing region is lower in energy than the conduction band in the electron extraction region, and the difference in energies of the two bands is greater than about 0.0768 eV.

33. The method of fabricating a solar cell structure recited in claim 30, wherein an intermediate band in the absorbing region is lower in energy than the conduction band in the electron extraction region, and the difference in energies of the two bands is greater than about 0.3072 eV.

34. The method of fabricating a solar cell structure recited in claim 30, wherein an intermediate band in the absorbing region is lower in energy than the conduction band in the electron extraction region, and the difference in energies of the two bands is greater than about 0.4608 eV.

35. The method of fabricating a solar cell structure recited in claim 30, wherein an intermediate band in the absorbing region is lower in energy than the conduction band in the hole extraction region, and the difference in energies of the two bands is greater than about 0.0768 eV.

36. The method of fabricating a solar cell structure recited in claim 30, wherein an intermediate band in the absorbing region is lower in energy than the conduction band in the hole extraction region, and the difference in energies of the two bands is greater than about 0.3072 eV.

37. The method of fabricating a solar cell structure recited in claim 30, wherein an intermediate band in the absorbing region is lower in energy than the conduction band in the hole extraction region, and the difference in energies of the two bands is greater than about 0.4608 eV.

38. The method of fabricating a solar cell structure recited in claim 30, wherein the conduction band of the absorbing region is lower in energy than the conduction band of the electron extraction region, and the difference in energies of the two bands is less than about 0.1536 eV.

39. The method of fabricating a solar cell structure recited in claim 30, wherein the conduction band of the absorbing region is lower in energy than the conduction band of the electron extraction region, and the difference in energies of the two bands is less than about 0.0768 eV.

40. The method of fabricating a solar cell structure recited in claim 30, wherein the conduction band of the absorbing region is about the same or higher in energy than the conduction band of the electron extraction region.

41. The method of fabricating a solar cell structure recited in claim 30, wherein the valence band of the absorbing region is higher in energy than the valence band of the hole extraction region, and the difference in energies of the two bands is less than about 0.1536 eV.

42. The method of fabricating a solar cell structure recited in claim 30, wherein the valence band of the absorbing region is higher in energy than the valence band of the hole extraction region, and the difference in energies of the two bands is less than about 0.0768 eV.

43. The method of fabricating a solar cell structure recited in claim 30, wherein the valence band in the absorbing region is about the same or higher in energy than the valence band in the hole extraction region.

44. The method of fabricating a solar cell structure recited in claim 30, wherein a dislocation density within the absorbing region is less than about 1×10⁸ cm⁻².

45. The method of fabricating a solar cell structure recited in claim 30, wherein a dislocation density within the absorbing region is less than about 1×10⁷ cm⁻².

46. The method of fabricating a solar cell structure recited in claim 30, wherein a dislocation density within the absorbing region is less than about 1×10⁶ cm⁻².

47. The method of fabricating a solar cell structure recited in claim 30, further comprising epitaxially growing a buffer region, wherein the buffer region is formed over the substrate and a remaining solar cell structure is formed over the buffer region.

48. The method of fabricating a solar cell structure recited in claim 30, wherein the substrate comprises a n-type substrate, the hole electron extraction region comprises an n-type hole extraction region and the electron extraction region comprises a p-type electron extraction region.

49. The method of fabricating a solar cell structure recited in claim 30, wherein the absorbing region comprises a dilute nitride semiconductor region comprising AlₙInₘGa₁₋ₙ₋ₘN_{c}AsᵥSbₖP_{1-c-v-k} where 0≦n, m, v, k≦1 and 0.001<c<0.2.

50. The method of fabricating a solar cell structure recited in claim 49, wherein a bandgap between an intermediate band of the absorbing region and either the valence band or the conduction band of the absorbing region is in the range of about 1.3 eV to about 1.6 eV and an overall bandgap of the absorbing region is in the range of about 2.2 eV to about 2.5 eV.

51. The method of fabricating a solar cell structure recited in claim 50, wherein a bandgap between an intermediate band of the absorbing region and either the valence band or the conduction band of the absorbing region is in the range of about 1.4 eV to about 1.5 eV and an overall bandgap of the absorbing region is in the range of about 2.3 eV to about 2.4 eV.

52. The method of fabricating a solar cell structure recited in claim 30, wherein the substrate comprises n-type GaP, the hole extraction region comprises n-type GaAsₓP₁₋ₓ where 0.35<x<0.6, the absorbing region comprises n-type GaAsₓN_{c}P_{1-x-c} where 0.005<c<0.2, and 0.37<x<0.77 and the electron extraction region comprises p-type GaP.

53. The method of fabricating a solar cell structure recited in claim 30, wherein the substrate comprises n-type GaP, the hole extraction region comprises n-type GaAsₓP₁₋ₓ where 0.4<x<0.54, the absorbing region comprises n-type GaAsₓN_{c}P_{1-x-c} where 0.015<c<0.05 and 0.47<x<0.67 and the electron extraction region comprises p-type GaP.

54. A solar cell structure, comprising:
a dilute nitride absorbing region located between a hole extraction region and an electron extraction region, wherein a bandgap between an intermediate band of the absorbing region and either the valence band or the conduction band of the absorbing region is in the range of about 1.3 eV to about 1.6 eV; an overall bandgap of the absorbing region is in the range of about 2.2 eV to about 2.5 eV; the bandgap between the conduction band in the absorbing region and the conduction band in the electron extraction region is less than about 0.1536 eV; and the bandgap between the valence band in the absorbing region and the valence band in the hole extraction region is less than about 0.1536 eV.

55. The solar cell of claim 53, wherein said dilute nitride absorbing layer comprises GaAsₓN_{c}P_{1-x-c} where 0.005<c<0.2, and 0.37<x<0.77; a bandgap between an intermediate band of the absorbing region and either the valence band or the conduction band of the absorbing region is in the range of about 1.4 eV to about 1.5 eV; an overall bandgap of the absorbing region is in the range of about 2.3 eV to about 2.4 eV; and the solar cell has a theoretical efficiency of greater than 55%.
